(19) United States
(12) Patent Application Publication
(10) Pub. No.: US 2021/0064258 A1
(43) Pub. Date: Mar. 4, 2021

(54) MEMORY SYSTEM

(71) Applicant: KIOXIA CORPORATION, Tokyo (JP)

(72) Inventors: Seiichiro SAKURAI, Yokohama Kanagawa (JP); Yuji IZUMI, Yokohama Kanagawa (JP)

(73) Assignee: KIOXIA CORPORATION, Tokyo (JP)

(21) Appl. No.: 16/806,192

(22) Filed: Mar. 2, 2020

(30) Foreign Application Priority Data
Sep. 2, 2019 (JP) 2019-159542

(51) Int. Cl. G06F 3/06; G11C 16/04; G06F 13/16

(52) U.S. Cl. CPC G06F 3/0634; G11C 16/0483; G06F 3/0604; G11C 16/08; G06F 3/068; G06F 13/1668; G06F 3/0659

(57) ABSTRACT

According to one embodiment, a memory system includes a memory controller and a non-volatile memory electrically connected to the memory controller. The non-volatile memory includes a memory chip having a plurality of planes. The memory chip includes a mode switching circuit and an input and output circuit. The mode switching circuit is configured to switch from a first mode to a second mode in response to a first command from the memory controller. The input and output circuit is configured to receive at least one of a command, an address, or data from the memory controller via a first bus when the mode switching circuit is in the first mode, and transmit, to the memory controller via the first bus, busy information indicating that at least one of the plurality of planes is in a busy state when the mode switching circuit is in the second mode.

### CROSS-REFERENCE TO RELATED APPLICATION(S)

This application is based upon and claims the benefit of priority from Japanese Patent Application No. 2019-159542, filed Sep. 2, 2019, the entire contents of which are incorporated herein by reference.

### FIELD

Embodiments described herein relate generally to a memory system.

### BACKGROUND

A memory controller receives a busy signal from a memory chip when one memory chip among a plurality of memory chips is in a busy state. The memory controller performs a status read to the plurality of memory chips based on the busy signal, and confirms which memory chip is in the busy state.

One memory chip includes a plurality of planes, and read may be performed in units of planes. The memory controller specifies the planes by a plane selection command, performs the status read, and confirms whether each plane is in the busy state.

Examples of related art include US Patent Application Publication No. 2015/0286411.

### DESCRIPTION OF THE DRAWINGS

FIG. 1 is a block diagram showing a configuration of a memory system according to a first embodiment connected to a host.

FIG. 2A is a block diagram showing a configuration of an input and output circuit, a control circuit, and the like of an NAND memory in the memory system according to the first embodiment.

FIG. 2B is a block diagram showing a configuration of a plurality of planes of the NAND memory in the memory system according to the first embodiment.

FIG. 3 is a flowchart showing processing of a memory controller and the NAND memory in the memory system according to the first embodiment.

FIG. 4 is a timing chart of each signal in a normal mode in the memory system according to the first embodiment.

FIG. 5 is a timing chart of each signal when the memory system according to the first embodiment is switched to a busy information mode.

FIG. 6 is a timing chart of each signal when 8-bit busy information in the memory system according to the first embodiment is added to a DQ signal.

FIG. 7 is a block diagram showing a configuration of a memory system according to a second embodiment connected to a host.

FIG. 8A is a block diagram showing a configuration of an input and output circuit, a control circuit, and the like of an NAND memory in the memory system according to the second embodiment.

FIG. 8B is a block diagram showing a configuration of a plurality of planes of the NAND memory in the memory system according to the second embodiment.

FIG. 9 is a flowchart showing processing of a memory controller and the NAND memory in the memory system according to the second embodiment.

FIG. 10 is a timing chart of each signal in a normal mode in the memory system according to the second embodiment.

FIG. 11 is a timing chart of each signal when the NAND memory in the memory system according to the second embodiment is switched to a busy information mode.

### DETAILED DESCRIPTION

Embodiments provide a memory system that can grasp a busy state in units of planes or memory chips without performing status read.

In general, according to one embodiment, a memory system includes a memory controller and a non-volatile memory electrically connected to the memory controller. The non-volatile memory includes a memory chip having a plurality of planes. The memory chip includes a mode switching circuit and an input and output circuit. The mode switching circuit is configured to switch from a first mode to a second mode in response to a first command from the memory controller. The input and output circuit is configured to receive at least one of a command, an address, or data from the memory controller via a first bus when the mode switching circuit is in the first mode, and transmit, to the memory controller via the first bus, busy information indicating that at least one of the plurality of planes is in a busy state when the mode switching circuit is in the second mode.

Hereinafter, a memory system according to an embodiment will be described in detail with reference to the drawings.

The drawings referred to are schematic views. In the following description, elements having the same functions and configurations are denoted by the same reference numerals.

### First Embodiment

Configuration of Memory System

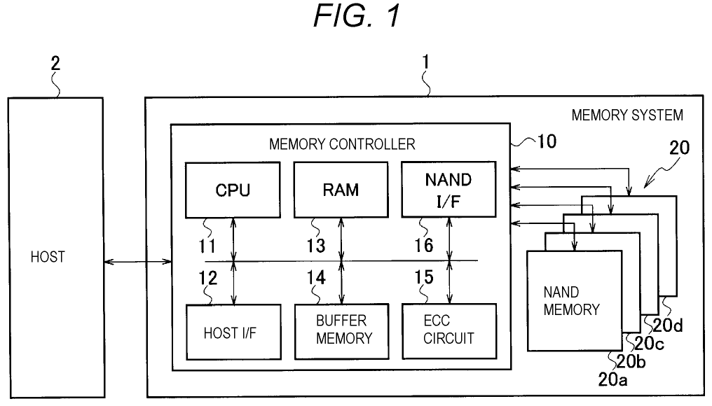

FIG. 1 is a block diagram showing a configuration of a memory system according to a first embodiment connected to a host. As shown in FIG. 1, a memory system 1 communicates with a host 2 (a host device). The memory system 1 stores data from the host 2 based on an instruction from the host 2.

The memory system 1 includes a plurality of non-volatile memories 20 (20a to 20d) and a memory controller 10 that controls the plurality of non-volatile memories 20. The non-volatile memory 20 is, for example, a NAND flash memory, a NOR flash memory, an Erasable Programmable Read Only Memory (EPROM), or an Electrically Erasable Programmable Read-Only Memory (EEPROM). Hereinafter, the non-volatile memory 20 may be referred to as the NAND memory 20. The memory system 1 is, for example, a memory card such as an SD™ card or a Solid State Drive (SSD).

The NAND memory 20 and the memory controller 10 may be, for example, chips sealed with resin in separate packages. The NAND memory 20 and the memory controller 10 may be one chip.

The plurality of NAND memories 20 have the same elements and connections. Here, one NAND memory 20 will be described as a representative. The description of one NAND memory 20 is also applied to other NAND memories 20.

Configuration of Memory Controller

The memory controller 10 includes, for example, a system-on-a-chip (SoC). The memory controller 10 responds to a request from the host 2. The memory controller 10 is a control device that commands read, write, erase, and the like to the NAND memory 20. The memory controller 10 writes data requested to be written from the host 2 to the NAND memory 20. The memory controller 10 reads data requested to be read from the host 2 from the NAND memory 20. The memory controller 10 transmits the data read from the NAND memory 20 to the host 2.

The memory controller 10 manages a memory space in the NAND memory 20. The management includes management of addresses and management of a state of the NAND memory 20.

The management of addresses includes mapping of a logical address and a physical address. The physical address is an address that specifies a storage area provided by the NAND memory 20. Specifically, the memory controller 10 is requested from the host 2 to write data. The mapping between the logical address of a write destination of the data requested to be written and the physical address of the storage area in the NAND memory 20 in which the data is written is managed by an address conversion table. The memory controller 10 acquires a physical address associated with a certain logical address from the address conversion table, and reads data from the storage area of the acquired physical address.

The management of the state of the NAND memory 20 includes management of the storage area of the NAND memory 20, wear leveling, garbage collection (compaction), and refreshing.

The memory controller 10 includes a Central Processing Unit (CPU) 11, a host interface (host I/F) 12, a Random Access Memory (RAM) 13, a buffer memory 14, and an Error Correcting Code (ECC) circuit 15 and an NAND interface (NAND I/F) 16.

A part or all of the functions of the host interface 12, the RAM 13, the ECC circuit 15, and the NAND interface 16 may be implemented by executing a firmware (program) loaded in the RAM 13 by the CPU 11 such as a processor. The CPU 11, the host interface 12, the RAM 13, the buffer memory 14, the ECC circuit 15, and the NAND interface 16 are connected to each other by a bus.

The CPU 11 controls the host interface 12, the RAM 13, the buffer memory 14, the ECC circuit 15, and the NAND interface 16. In response to a write request received from the host 2, the CPU 11 issues a write command to the NAND memory 20. The operation is the same in the case of read and erase.

The host interface 12 is a hardware interface that communicates with the outside. For example, the host interface 12 transfers a request and data received from the outside to the CPU 11 and the RAM 13.

The RAM 13 is an SRAM, a DRAM, or the like. The RAM 13 is used as a work area of the CPU 11, for example. The buffer memory 14 is a memory that temporarily stores data received by the memory controller 10 from the NAND memory 20 and the host 2, and has a function as a buffer.

The ECC circuit 15 performs Error Checking and Correcting of data, and is connected to the NAND interface 16. The ECC circuit 15 generates parity based on write data when data is written.

The ECC circuit 15 performs error correction operation on data read from the NAND memory 20. The ECC circuit 15 generates a syndrome from read data and parity when data is read, detects an error, and corrects the detected error. When a code error of the read data is within an error correction capability, the ECC circuit 15 can restore correct data from the read data.

The NAND interface 16 is a hardware interface that is connected to the NAND memory 20 and performs communication between the memory controller 10 and the NAND memory 20. The NAND interface 16 transmits and receives signals in accordance with the NAND interface. The signals in accordance with the NAND interface include, for example, various control signals and input and output signals DQ.

Configuration of NAND Memory

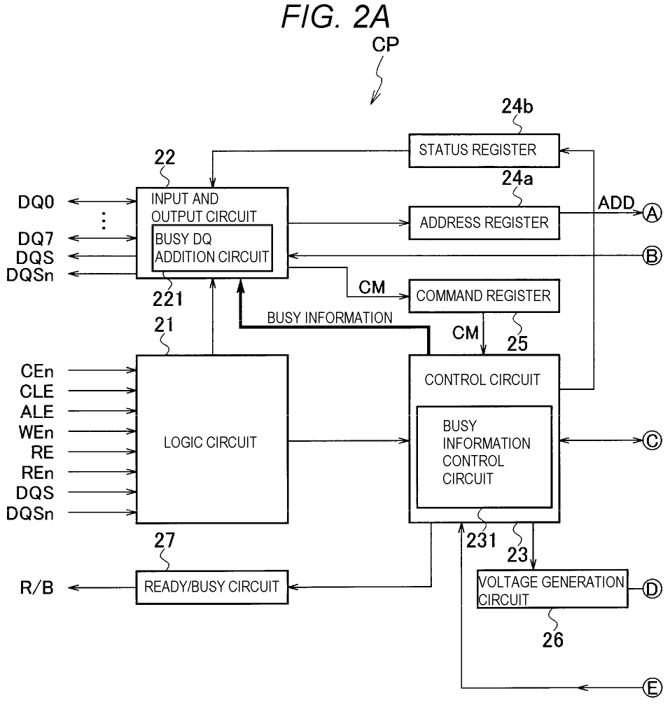

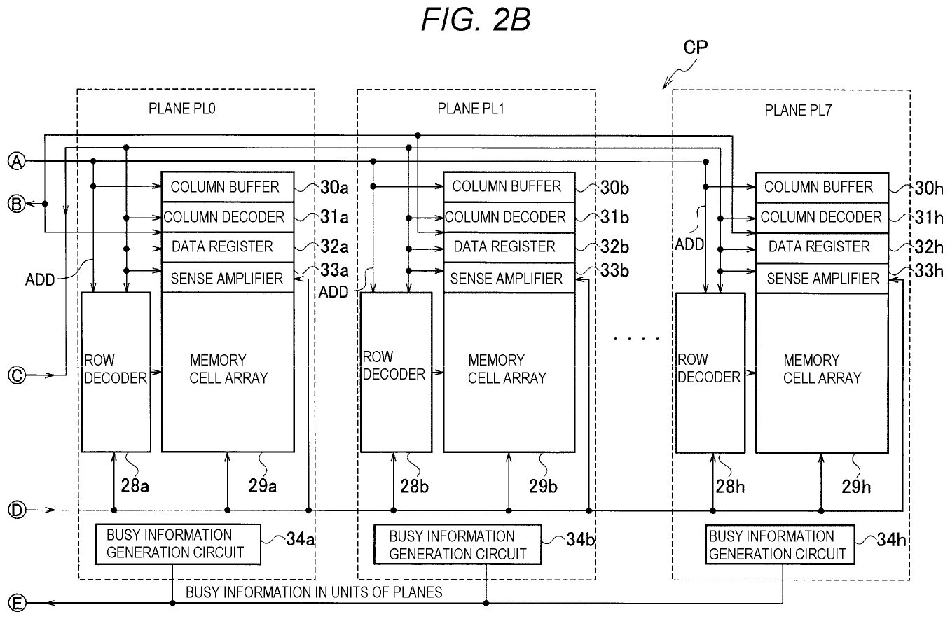

FIG. 2A is a block diagram showing a configuration of an input and output circuit, a control circuit, and the like of an NAND memory in the memory system according to the first embodiment. FIG. 2B is a block diagram showing a configuration of a plurality of planes of the NAND memory in the memory system according to the first embodiment. A, B, C, D, and E shown in FIG. 2A are connected to A, B, C, D, and E shown in FIG. 2B. The NAND memory 20 includes one or more memory chips. Here, a case in which the NAND memory 20 includes one memory chip will be described. As shown in FIG. 2A, the memory chip includes a logic circuit 21, an input and output circuit 22, a control circuit 23, an address register 24a, a status register 24b, a command register 25, a voltage generation circuit 26, and a ready/busy circuit 27.

The logic circuit 21 receives a chip enable signal CEn, a command latch enable signal CLE, an address latch enable signal ALE, a write enable signal WEn, a read enable signal RE, a read enable signal REn, a data strobe signal DQS, and a data strobe signal DQSn from the memory controller 10. The logic circuit 21 transmits the above signals to the input and output circuit 22 and the control circuit 23 as necessary.

The chip enable signal CEn is a signal asserted at a low level and is used for activating the memory chip, which is asserted when accessing the memory chip. The command latch enable signal CLE and the address latch enable signal ALE are signals that notify the memory chip that input signals to the memory chip are a command and an address, respectively. The write enable signal WEn is a signal asserted at a low level and is used for taking an input signal into the memory chip. The read enable signal RE asserted at a high level and the read enable signal REn asserted at a low level are signals for reading an output signal from the memory chip. The signal DQS and the signal DQSn are data strobe signals for the input signal and the output signal.

The input and output circuit 22 receives a signal from the logic circuit 21, transmits the signal DQS and the signal DQSn to the memory controller 10, and transmits and receives a plurality of input and output signals DQ (DQ0 to DQ7, hereinafter referred to as a DQ signal) to and from the memory controller 10. The DQ signal has, for example, a width of 8 bits, and includes a command (CMD), write data and read data (DATA), an address signal (ADD), and various types of management data. The DQ signal is an example of a first bus. When a mode switching circuit described below is in a first mode, the input and output circuit 22 receives any one of the command, the address, and the data from the memory controller 10 via the DQ signal.

When the DQ signal is an address, the input and output circuit 22 transmits the address to the address register 24a; when the DQ signal is a command, the input and output circuit 22 transmits the command to the command register 25. In particular, when receiving a switching command CM (a first command) from the memory controller 10, the input and output circuit 22 sends the switching command CM to the command register 25. Further, as shown in FIG. 2B, when the DQ signal is write data when data is written, the input and output circuit 22 transmits the write data to sense amplifiers 33a to 33h. When data is read, the input and output circuit 22 transmits read data transferred from the sense amplifiers 33a to 33h to the memory controller 10 together with the signals DQS/DQSn.

As shown in FIG. 2A, the address register 24a stores an address from the input and output circuit 22. The status register 24b stores various types of status information of the memory chip. The command register 25 stores a command from the input and output circuit 22.

The control circuit 23 controls the voltage generation circuit 26, row decoders 28a to 28h, the status register 24b, and the ready/busy circuit 27 at a timing when various signals are received by the logic circuit 21 in accordance with the switching command CM from the command register 25, for example.

The control circuit 23 also functions as a mode switching circuit that switches from the first mode to a busy information mode (a second mode) in response to the switching command CM from the command register 25. When the control circuit 23 switches to the busy information mode, the control circuit 23 operates as a master, and the memory controller 10 operates as a slave. When the busy information mode is released, the control circuit 23 operates as a slave, and the memory controller 10 operates as a master.

The voltage generation circuit 26 generates a voltage based on an instruction from the control circuit 23, and supplies the generated voltage to memory cell arrays 29a to 29h, the row decoders 28a to 28h, and the sense amplifiers 33a to 33h.

Based on the signal from the control circuit 23, the ready/busy circuit 27 transmits a ready/busy signal R/B indicating whether the memory chip is in a ready state (a state in which an instruction from the memory controller 10 can be received) or a busy state (a state in which an instruction from the memory controller 10 cannot be received) to the memory controller 10. The ready/busy signal R/B is an example of a second bus.

As shown in FIG. 2B, a memory chip CP includes a plurality of planes PL0 to PL7. The number of planes in the memory chip is not limited to eight. The number of the DQ signals DQ0 to DQ7 (8) to be transmitted to and received from the memory controller 10 and the number of the planes (8) in the memory chip coincide with each other. However, these numbers may be different from each other. Each of the plurality of planes PL0 to PL7 includes, as an independent peripheral circuit, a row decoder, a memory cell array, a column buffer, a column decoder, a data register, a sense amplifier, and a busy information generation circuit.

The memory controller 10 may simultaneously perform erase processing, write operation, and read operation on the planes PL0 to PL7. That is, the memory controller 10 may operate the planes PL0 to PL7 in parallel. The memory controller 10 may execute the erase processing, the write operation, and the read operation individually for the planes PL0 to PL7. That is, the memory controller 10 may perform the write operation and the read operation in units of planes.

The plane PL0 includes the row decoder 28a, the memory cell array 29a, a column buffer 30a, a column decoder 31a, a data register 32a, the sense amplifier 33a, and a busy information generation circuit 34a. The plane PL1 includes the row decoder 28b, the memory cell array 29b, a column buffer 30b, a column decoder 31b, a data register 32b, the sense amplifier 33b, and a busy information generation circuit 34b.

The planes PL2 to PL6 are constituted similarly to the planes PL0 and PL1. The plane PL7 includes the row decoder 28h, the memory cell array 29h, a column buffer 30h, a column decoder 31h, a data register 32h, the sense amplifier 33h, and a busy information generation circuit 34h.

Each of the memory cell arrays 29a to 29h is a storage unit including a plurality of blocks. The memory cell arrays 29a to 29h are connected to the voltage generation circuit 26, the row decoders 28a to 28h, and the sense amplifiers 33a to 33h. Data in each block of the memory cell arrays 29a to 29h is collectively erased. Each block includes a plurality of cell transistors (memory cells) associated with bit lines and word lines. The cell transistor stores write data from the memory controller 10 in a non-volatile manner.

The row decoders 28a to 28h decode row addresses specifying row directions of the memory cell arrays 29a to 29h. The row decoders 28a to 28h receive an address signal ADD from the address register 24a. The row decoders 28a to 28h select one block based on the address signal ADD and transfer a voltage from the voltage generation circuit 26 to the selected block.

The row decoders 28a to 28h select a word line corresponding to a cell transistor to be subjected to a read operation and a write operation. The row decoders 28a to 28h apply desired voltages to the selected word line and the unselected word line, respectively.

The column buffers 30a to 30h store column addresses specifying column directions of the memory cell arrays 29a to 29h. The column decoders 31a to 31h decode column addresses specifying column directions of the memory cell arrays 29a to 29h stored in the column buffers 30a to 30h. The control circuit 23 transfers write data to the data registers 32a to 32h at the time of write and reads data from the data registers 32a to 32h at the time of read according to a decoding result.

The data registers 32a to 32h temporarily store write data or read data of one page.

At the time of read, the sense amplifiers 33a to 33h sense data read from the memory cell arrays 29a to 29h and transfer the data to the data registers 32a to 32h. At the time of write, data in the data registers 32a to 32h is transferred to the memory cell arrays 29a to 29h.

As shown in FIG. 2A, the control circuit 23 includes a busy information control circuit 231. The busy information control circuit 231 manages busy information from the busy information generation circuits 34a to 34h, and outputs the busy information to the input and output circuit 22.

As shown in FIG. 2B, the busy information generation circuits 34a to 34h are provided corresponding to the planes PL0 to PL7. When the planes PL0 to PL7 are in the busy state after the control circuit 23 switches to the busy information mode, the busy information generation circuits 34a to 34h generate busy information and output the generated busy information to the busy information control circuit 231 in the control circuit 23. The busy information of each plane is represented by information of 0 or 1.

As shown in FIG. 2A, the input and output circuit 22 includes a busy DQ addition circuit 221. When the busy signal is at a low level, the busy DQ addition circuit 221 adds the busy information from the busy information control circuit 231 to the DQ signal, and transmits the added DQ signal to the memory controller 10.

The input and output circuit 22 may transmit busy information from the busy information generation circuits 34a to 34h to the memory controller 10 regardless of the level of the busy signal.

### Operation of Memory System According to First Embodiment

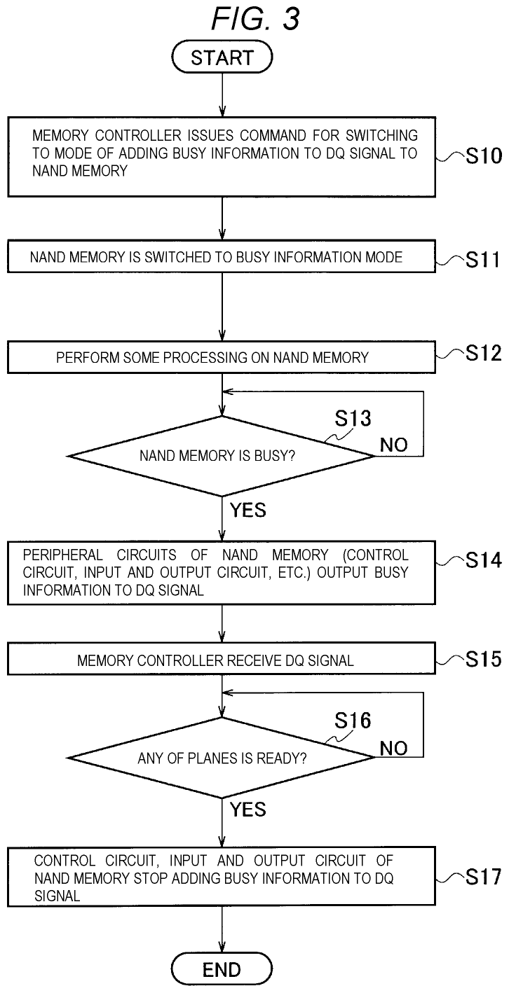

Next, operation of the memory controller 10 and the NAND memory 20 in the memory system according to the first embodiment constituted as described above will be described with reference to FIGS. 3 to 5.

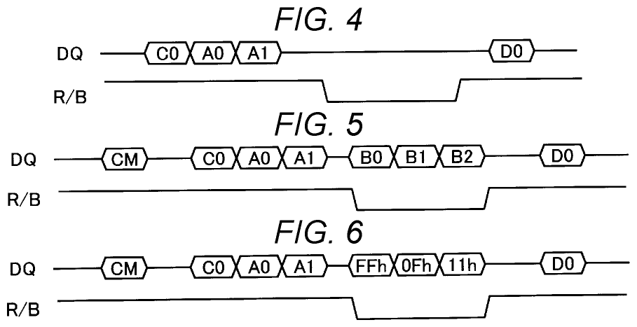

In FIGS. 4 and 5, DQ indicates a DQ signal, and R/B indicates a ready/busy signal. In R/B, the high level is a ready signal, and a low level is a busy signal.

Normal Mode

First, the operation in the normal mode will be described with reference to a timing chart shown in FIG. 4. When receiving a first ready signal from the NAND memory 20, the memory controller 10 transmits a DQ signal obtained by adding a command C0, an address A0, and an address A1 to the NAND memory 20.

When receiving a busy signal from the NAND memory 20, the memory controller 10 does not transmit a DQ signal including a command or the like to the NAND memory 20. When receiving a next ready signal from the NAND memory 20, the memory controller 10 transmits a DQ signal to which data D0 is added to the NAND memory 20.

Busy Information Mode

Next, operation at the time of switching to the busy information mode will be described with reference to a flowchart shown in FIG. 3 and a timing chart shown in FIG. 5.

First, the memory controller 10 issues a command for switching to the busy information mode by adding busy information to the DQ signal to the NAND memory 20 (step S10). At this time, as shown in FIG. 5, when receiving the first ready signal from the NAND memory 20, the memory controller 10 transmits the DQ signal to which the switching command CM for switching to the busy information mode is added to the NAND memory 20.

Next, the NAND memory 20 is switched to the busy information mode (step S11). In this case, the input and output circuit 22 receives the switching command CM from the memory controller 10, and outputs the switching command CM to the command register 25. The control circuit 23 switches to the busy information mode based on the switching command CM from the command register 25.

Next, the memory controller 10 performs some processing on the NAND memory 20 (step S12). At this time, as shown in FIG. 5, the memory controller 10 transmits the DQ signal to which the command C0, the address A0, and the address A1 are added to the NAND memory 20.

Next, it is determined whether or not the NAND memory 20 is in the busy state (step S13). When the NAND memory 20 receives, for example, a write command from the memory controller 10, the state of the NAND memory 20 transits from the ready state to the busy state.

When the NAND memory 20 is in the busy state, the control circuit 23 and the input and output circuit 22 of the NAND memory 20 output the busy information to the DQ signal (step S14). At this time, as shown in FIG. 5, the NAND memory 20 transmits the busy signal to the memory controller 10.

In steps S13 and S14, when at least one corresponding plane of the planes PL0 to PL7 is busy after the control circuit 23 switches to the busy information mode, the busy information generation circuits 34a to 34h generate busy information of the plane. The busy information generation circuits 34a to 34h output the generated busy information to the busy information control circuit 231 in the control circuit 23 (E in FIGS. 2A and 2B).

The busy information control circuit 231 manages the busy information from the busy information generation circuits 34a to 34h, and outputs the managed busy information to the busy DQ addition circuit 221 in the input and output circuit 22.

The busy DQ addition circuit 221 adds the busy information from the busy information control circuit 231 to the DQ signal. Specifically, as shown in FIG. 5, the busy DQ addition circuit 221 adds busy information B0, B1, and B2 from the busy information control circuit 231 to the DQ signal and transmits the DQ signal to the memory controller 10 while the busy signals are output. A specific example of the busy information B0, B1, and B2 will be described below with reference to FIG. 6.

Next, the memory controller 10 receives the DQ signal to which the busy information B0, B1, B2 is added (step S15). When the memory controller 10 receives the busy signal, the memory controller 10 interprets the information B0, B1, and B2 added to the DQ signal as busy information of each plane, and performs processing.

Next, the control circuit 23 determines whether any of the planes PL0 to PL7 is in the ready state (step S16).

When one of the planes PL0 to PL7 is in the ready state, the control circuit 23 notifies the input and output circuit 22 of the ready state. When receiving the notification from the control circuit 23, the input and output circuit 22 stops adding the busy information from the busy information generation circuits 34a to 34h to the DQ signal (step S17).

Specifically, when any one of the planes PL0 to PL7 is in the ready state, the busy DQ addition circuit 221 stops the processing of adding the busy information from the busy information generation circuits 34a to 34h to the DQ signal. At this time, the R/B signal is at a low level if any of the planes is busy. The R/B signal is at a high level when all the planes are ready.

The memory controller 10 constantly monitors the busy information from the NAND memory 20, and when any one of the planes PL0 to PL7 is in the ready state, the memory controller 10 may specify the ready plane and perform input and output processing on the specified plane. For example, the memory controller 10 transmits the DQ signal to which the data D0 is added to the NAND memory 20.

### One Example of Addition of Busy Information

Next, operation when 8-bit busy information of the memory system according to the first embodiment is added to the DQ signal will be described with reference to a timing chart shown in FIG. 6.

The busy DQ addition circuit 221 converts binary 8-bit busy information represented by 0 or 1 of 8 planes from the busy information control circuit 231 into hexadecimal 8-bit busy information, and adds the busy information to the DQ signal. When any of the planes is in the busy state, the busy DQ addition circuit 221 adds the busy information to the DQ signal.

When all of the planes PL0 to PL7 are in the busy state, upper 4 bits “1111” of the binary 8-bit busy information “11111111” are converted into “F” in hexadecimal, and lower 4 bits “1111” are converted into “F” in hexadecimal. The hexadecimal 8-bit busy information is “FF”.

When the planes PL0 to PL3 are in the busy state and the planes PL4 to PL7 are in the ready state, the upper 4 bits “0000” of the binary 8-bit busy information “00001111” are converted into “0” in hexadecimal, and the lower 4 bits “1111” are converted into “F” in hexadecimal. The hexadecimal 8-bit busy information is “OF”.

When the planes PL0 and PL4 are in the busy state and the other planes are in the ready state, the upper 4 bits “0001” of the binary 8-bit busy information “00010001” are converted into “1” in hexadecimal, and the lower 4 bits “0001” are converted into “1” in hexadecimal. The hexadecimal 8-bit busy information is “11”.

As described above, the number of DQ signals and the number of planes in the memory chip may be different. When the number of DQ signals is greater than the number of planes in the memory chip, the memory controller 10 may ignore a DQ signal to which a busy state of a plane is not added. When the number of DQ signals is smaller than the number of planes in the memory chip, the busy DQ addition circuit 221 may add a busy state of a plurality of planes to one DQ signal.

### Effects of Memory System According to First Embodiment

In this manner, according to the memory system according to the first embodiment, the memory chip CP includes a plurality of planes PL0 to PL7. When receiving a switching command from the memory controller 10, the control circuit 23 switches to the busy information mode. After the control circuit 23 switches to the busy information mode, the busy information generation circuits 34a to 34h generate busy information of a plane for each of the planes PL0 to PL7 when the plane is in the busy state. The input and output circuit 22 transmits the busy information for each plane generated by the busy information generation circuits 34a to 34h to the memory controller 10.

Therefore, the memory controller 10 can grasp the busy state in units of planes without performing status read. For this reason, time for the status read in related art can be used for another processing, and the processing speed can be increased.

When any one of the planes PL0 to PL7 is in the ready state, the control circuit 23 releases the busy information mode, and the input and output circuit 22 can stop the transmission of the busy information to the memory controller 10 when the busy information mode is released.

The memory controller 10 monitors the busy information from the NAND memory 20, and when any one of the planes PL0 to PL7 is in the ready state, it is possible to perform input and output processing of data on the NAND memory 20.

The busy DQ addition circuit 221 adds busy information of a plurality of planes from the plurality of busy information generation circuits 34a to 34h to a plurality of DQ signals in the input and output circuit 22 and transmits the busy information to the memory controller 10. Therefore, the busy information is not transmitted to the memory controller 10 by a circuit other than the input and output circuit 22 or by a signal different from the DQ signals, and the configuration of the NAND memory 20 can be simplified.

When the busy signal is at an L level, the input and output circuit 22 adds the busy information of the plurality of planes from the plurality of busy information generation circuits 34a to 34h to the plurality of DQ signals and transmits the busy information to the memory controller 10. Therefore, the memory controller 10 knows that the information that is added to the plurality of DQ signals and is received when the busy signal of the L level is received is busy information.

The busy information generation circuits 34a to 34h are provided corresponding to the plurality of planes, and the input and output circuit 22 adds busy information of the plurality of planes generated by the busy information generation circuits 34a to 34h to a plurality of DQ signals and transmits the busy information to the memory controller 10. Therefore, the memory controller 10 can grasp which plane is in the busy state.

When any one of the planes PL0 to PL7 is in the ready state, the busy DQ addition circuit 221 can stop the processing of adding the busy information from the busy information generation circuits 34a to 34h to the plurality of DQ signals.

### Second Embodiment

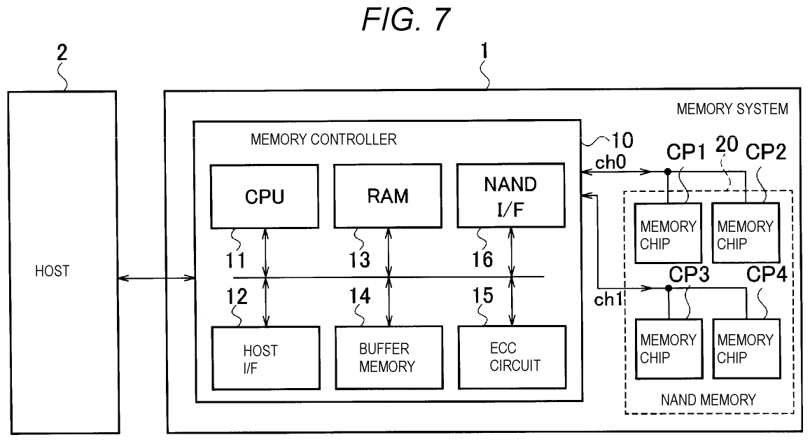

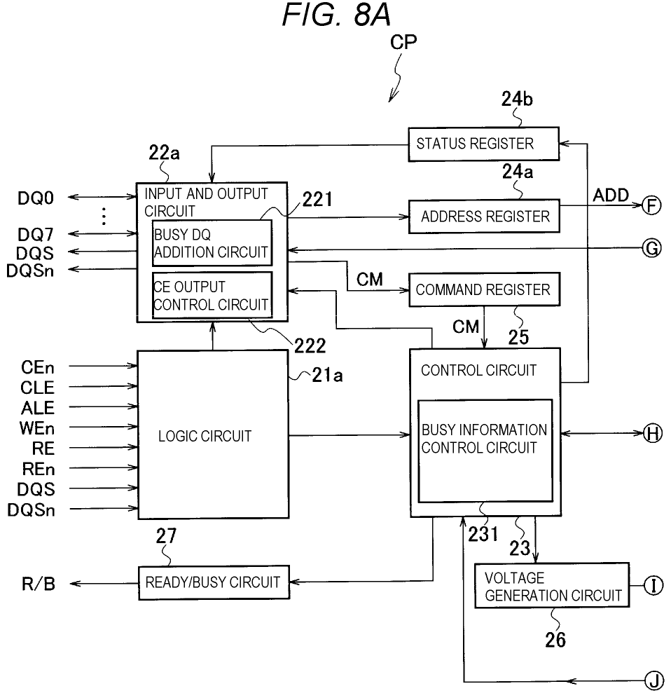

FIG. 7 is a block diagram showing a configuration of a memory system according to a second embodiment connected to a host. The memory system according to the second embodiment selects memory chips CP by a chip enable signal CEn and grasps a busy state in units of memory chips.

In FIG. 7, the NAND memory 20 includes a plurality of memory chips CP1 to CP4. The memory controller 10 includes two channels ch0 and chl. The memory controller 10 may include one or three or more channels. Two memory chips CP1 and CP2 are connected to the channel ch0, and two memory chips CP3 and CP4 are connected to the channel chl. The number of memory chips is not limited to four.

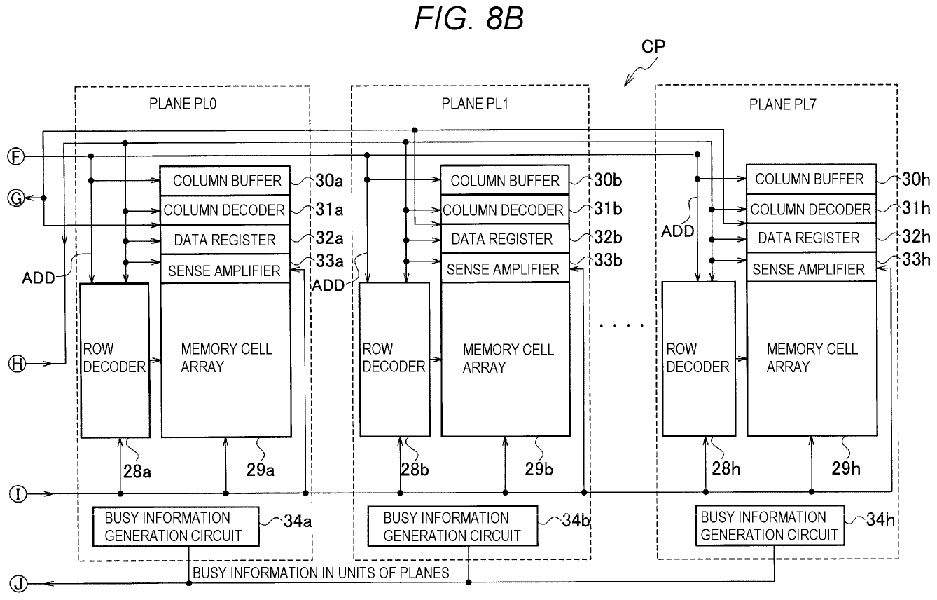

FIG. 8A is a block diagram showing a configuration of an input and output circuit, a control circuit, and the like of an NAND memory in the memory system according to the second embodiment. FIG. 8B is a block diagram showing a configuration of a plurality of planes of the NAND memory in the memory system according to the second embodiment. F, G, H, I, and J shown in FIG. 8A are connected to F, G, H, I, and J shown in FIG. 8B. Each of the plurality of memory chips CP1 to CP4 differs in the configuration of a logic circuit 21a and an input and output circuit 22a from the configuration of the memory chip shown in FIGS. 2A and 2B.

The memory controller 10 selects a memory chip CP by the chip enable signal CEn. When the logic circuit 21a in the selected memory chip CP receives the chip enable signal CEn from the memory controller 10, the logic circuit 21a outputs the chip enable signal CEn to the input and output circuit 22a. The chip enable signal CEn is a signal for enabling the memory chip, and is asserted at a low level.

The input and output circuit 22a includes a CE output control circuit 222. For example, the logic circuit 21a of the memory chip CP1 receives the chip enable signal CEn from the memory controller 10. At this time, the chip enable signal CEn is input from the logic circuit 21a to the CE output control circuit 222 of the memory chip CP1. The CE output control circuit 222 controls the output of the DQ signal by controlling the input and output circuit 22a based on the chip enable signal CEn.

### Operation of Memory System According to Second Embodiment

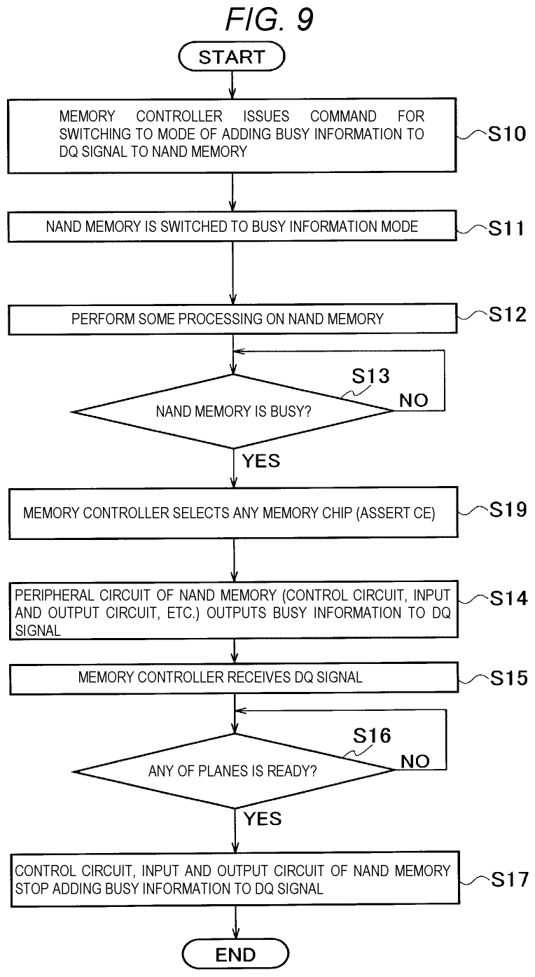

Next, operation of the memory controller 10 and the NAND memory 20 in the memory system according to the second embodiment constituted as described above will be described with reference to FIGS. 9 to 11.

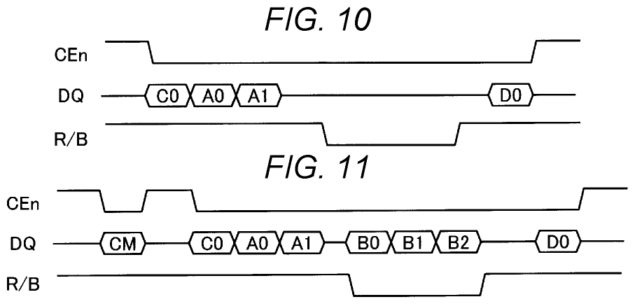

CEn shown in FIGS. 10 and 11 indicates a chip enable signal. DQ indicates a DQ signal, and R/B indicates a ready/busy signal. In R/B, an H level is a ready signal, and a low level is a busy signal.

Normal Mode

First, the operation in a normal mode will be described with reference to a timing chart shown in FIG. 10. When receiving a first ready signal from the NAND memory 20, the memory controller 10 asserts the chip enable signal CEn at a low level. The memory controller 10 transmits a DQ signal to which a command C0, an address A0, and an address A1 are added to the NAND memory 20.

When receiving a busy signal from the NAND memory 20 at the next timing, the memory controller 10 does not transmit the DQ signal including a command or the like to the NAND memory 20. When receiving a next ready signal from the NAND memory 20, the memory controller 10 transmits the DQ signal to which data D0 is added to the NAND memory 20.

Busy Information Mode

Next, operation at the time of switching to a busy information mode will be described with reference to a flowchart shown in FIG. 9 and a timing chart shown in FIG. 11.

Since the processing of steps S10 to S13 shown in FIG. 9 are the same as those shown in FIG. 3, the description thereof will be omitted.

In step S13, when the NAND memory 20 is in the busy state, the memory controller 10 selects any memory chip by asserting the chip enable signal CEn at a low level as shown in FIG. 11 (step S19). The memory controller 10 selects, for example, the memory chip CP1.

When the logic circuit 21a of the selected memory chip CP1 receives the chip enable signal CEn from the memory controller 10, the CE output control circuit 222 of the memory chip CP1 receives the chip enable signal CEn from the logic circuit 21a. The CE output control circuit 222 of the memory chip CP1 controls the output of the DQ signal by controlling the input and output circuit 22a based on the chip enable signal CEn.

Specifically, only when the chip enable signal CEn is asserted in the memory chip CP1, the busy DQ addition circuit 221 in the input and output circuit 22a adds the busy information to the DQ signal and transmits the DQ signal to the memory controller 10 (step S14). At this time, as shown in FIG. 11, the NAND memory 20 transmits the busy signal to the memory controller 10.

Since the processing of steps S15 to S18 are the same as those shown in FIG. 3, the description thereof will be omitted.

### Effects of Memory System According to Second Embodiment

In this manner, according to the memory system according to the second embodiment, the memory controller 10 selects the memory chip CP by the chip enable signal CEn. The logic circuit 21a in the selected memory chip CP receives the chip enable signal CEn from the memory controller 10.

The CE output control circuit 222 controls the output of the DQ signal by controlling the input and output circuit 22 based on the chip enable signal CEn from the logic circuit 21a. Therefore, only in the selected memory chip CP, the busy DQ addition circuit 221 adds the busy information to the DQ signal and transmits the DQ signal to the memory controller 10.

Therefore, the memory controller 10 can grasp the busy state in units of memory chips without performing status read. For this reason, time for the status read in related art can be used for another processing, and the processing speed can be increased.

In the memory systems according to the first and second embodiments, the control circuit 23 switches the mode between the normal mode and the busy information mode as a mode switching circuit. Instead of the control circuit 23, for example, the input and output circuit 22 may switch between the normal mode and the busy information mode as the mode switching circuit.

In the memory systems according to the first and second embodiments, the control circuit 23 directly outputs the busy information from the plurality of busy information generation circuits 34a to 34h to the input and output circuit 22. The control circuit 23 may output the busy information from the plurality of busy information generation circuits 34a to 34h to the status register 24b, for example, and the input and output circuit 22 may add the busy information from the status register 24b to the DQ signal.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a memory controller; and
a non-volatile memory communicatively connected to the memory controller, wherein
the non-volatile memory includes a memory chip having a plurality of planes,
the memory chip includes:
a mode switching circuit configured to switch from a first mode to a second mode in response to a first command from the memory controller; and
an input and output circuit,
the input and output circuit configured to:
receive at least one of: a second command, an address, or data from the memory controller via a first bus when the mode switching circuit is in the first mode, and
transmit, to the memory controller via the first bus, busy information indicating that at least one of the plurality of planes is in a busy state when the mode switching circuit is in the second mode.

2. The memory system according to claim 1, wherein
the input and output circuit is configured to stop transmitting the busy information to the memory controller when any one of the plurality of planes is in a ready state.

3. The memory system according to claim 1, wherein
the memory controller is configured to monitor the busy information transmitted from the memory chip, and perform input and output processing of data via the first bus to the memory chip when any one of the plurality of planes is in a ready state.

4. The memory system according to claim 1, wherein
the first bus includes a plurality of input and output signals, and a number of the plurality of input and output signals is equal to a number of the plurality of planes.

5. The memory system according to claim 4, wherein
the input and output circuit is configured to add the busy information of each plane to the plurality of input and output signals and transmit the input and output signals to the memory controller.

6. The memory system according to claim 5, wherein
the memory chip further includes a ready/busy circuit configured to transmit, to the memory controller via a second bus, a ready/busy signal indicating whether one of the plurality of planes is in a ready state or the busy state, and
the input and output circuit is configured to add the busy information of each plane to the plurality of input and output signals when the ready/busy signal indicates the busy state.

7. The memory system according to claim 5, wherein
the input and output circuit is configured to stop processing of adding the busy information of each plane to the plurality of input and output signals when any one of the plurality of planes is in a ready state.

8. The memory system according to claim 5, wherein
the non-volatile memory includes a plurality of memory chips connected to the memory controller, and
the memory controller is configured to select one of the memory chips by a chip enable signal, the input and output circuit is configured to add the busy information of each plane to the plurality of input and output signals only when the chip enable signal from the memory controller is asserted.

9. A method comprising:
receiving, by a non-volatile memory from a memory controller, a first command;
switching, by the non-volatile memory, the non-volatile memory from a first mode to a second mode in response to receiving the first command;
receiving, the non-volatile memory, at least one of: a second command, an address, or data from the memory controller via a first bus when the non-volatile memory is in the first mode; and
transmitting, by the non-volatile memory to the memory controller via the first bus, busy information indicating that at least one of the plurality of planes of the non-volatile memory is in a busy state when the non-volatile memory is in the second mode.

10. The method of claim 9, further comprising:
stopping, by the non-volatile memory, transmitting the busy information to the memory controller when any of the plurality of planes is in a ready state.

11. The method of claim 9, wherein
the first bus includes a plurality of input and output signals, and a number of the plurality of input and output signals is equal to a number of the plurality of planes.

12. The method of claim 11, further comprising:
adding, by the non-volatile memory, the busy information to the plurality of input and output signals and transmit the input and output signals to the memory controller.

13. The method of claim 12, further comprising:
stopping, by the non-volatile memory, processing of adding the busy information to the plurality of input and output signals when any of the plurality of planes is in a ready state.
